(19) United States
(12) Patent Application Publication
(10) Pub. No.: US 2026/0231522 A1
(43) Pub. Date: Aug. 6, 2026

(54) STACKED TRANSISTORS HAVING CHANNEL REGIONS WITH DIFFERENT CRYSTAL ORIENTATIONS

(71) Applicant: Taiwan Semiconductor Manufacturing Co., Ltd., Hsinchu (TW)

(72) Inventors: Yu-Hsien Chiang, Hsinchu (TW); Kuan-Kan Hu, Hsinchu (TW); Che Chi Shih, Taoyuan (TW); Jui-Chien Huang, Hsinchu (TW); Ku-Feng Yang, Baoshan Township (TW); Szuya Liao, Zhubei (TW)

(21) Appl. No.: 19/228,117

(22) Filed: Jun. 4, 2025

Related U.S. Application Data
(60) Provisional application No. 63/754,965, filed on Feb. 6, 2025.

(51) Int. Cl. H10D 84/85; H10D 30/00; H10D 30/01; H10D 62/10; H10D 62/40; H10D 62/60; H10D 62/832; H10D 64/01; H10D 84/01

(52) U.S. Cl. CPC H10D 84/856; H10D 30/0191; H10D 30/502; H10D 62/115; H10D 62/121; H10D 62/405; H10D 62/60; H10D 62/832; H10D 64/017; H10D 84/0167; H10D 84/851

(57) ABSTRACT

A semiconductor device and the method of forming the same are provided. The semiconductor device may include a first nanostructure, a first source/drain region on a sidewall of the first nanostructure, a first gate structure around the first nanostructure, a second nanostructure over the first nanostructure, a second source/drain region on a sidewall of the second nanostructure, and a second gate structure around the second nanostructure. The first nanostructure may comprise a first material with a first composition and a first crystal orientation. The second nanostructure may comprise a second material with a second composition and a second crystal orientation. The first composition may be different from the second composition, and the first crystal orientation may be different from the second crystal orientation.

### PRIORITY CLAIM AND CROSS-REFERENCE

This application claims the benefit of U.S. Provisional Application No. 63/754,965, filed on Feb. 6, 2025, which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example a stacking transistor in accordance with some embodiments.

FIGS. 2A, 2B, 3, 4, 5, 6, 7, 8, 9, and 10 are various views of intermediate stages in the manufacturing of a stacking transistor in accordance with some embodiments.

FIGS. 11, 12, and 13 are various views of intermediate stages in the manufacturing of a stacking transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor device and methods of forming the same. The semiconductor device may be a stacking transistor comprising upper transistors and lower transistors that are vertically stacked. The upper and lower transistors may include gate structures wrapping around respective semiconductor nanostructures (e.g., channel regions) and source/drain regions on sidewalls of the respective semiconductor nanostructures. The semiconductor nanostructures of the upper transistors and the lower transistors may be formed over semiconductor substrates with different crystal orientations, which may lead to the semiconductor nanostructures of the upper transistors and the lower transistors having materials with different compositions and crystal orientations. As a result, the carrier mobilities in the channel regions of the upper transistors and the lower transistors may be both improved, thereby improving the performance and reliability of the stacking transistor.

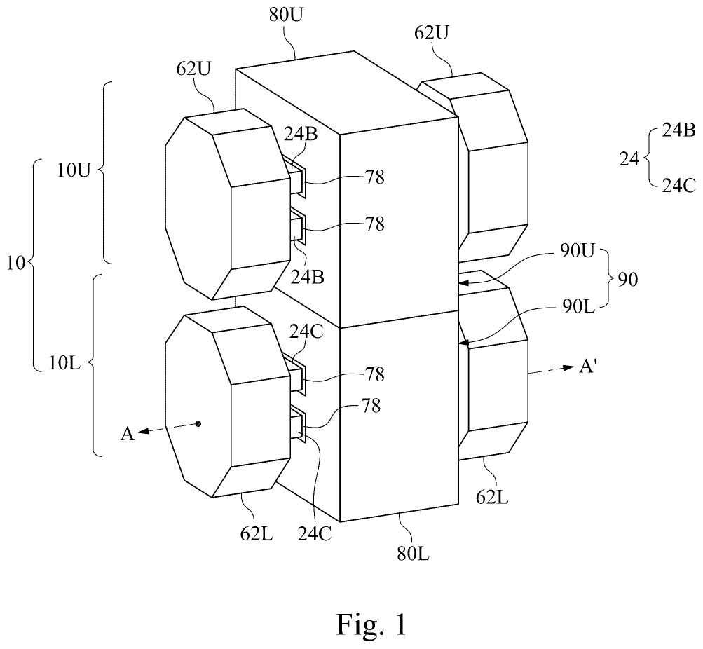

FIG. 1 illustrates an example of a stacking transistor 10 in accordance with some embodiments. FIG. 1 is a perspective view, and some features of the stacking transistor are omitted for illustration clarity. The stacking transistor includes multiple vertically stacked FETs. For example, a stacking transistor may include a lower nanostructure-FET 10L of a first device type (e.g., n-type or p-type) and an upper nanostructure-FET 10U of a second device type (e.g., p-type or n-type). When the stacking transistor is a Complementary Field-Effect Transistors (CFET), the second device type of the upper nanostructure-FET 10U is opposite to the first device type of the lower nanostructure-FET 10L. The upper nanostructure-FETs 10U and lower nanostructure-FET 10L include semiconductor nanostructures 24 (including semiconductor nanostructures 24B and semiconductor nanostructures 24C), where the semiconductor nanostructures 24 act as the channel regions for the nanostructure-FETs. The semiconductor nanostructures 24C are for the lower nanostructure-FET 10L, and selected semiconductor nanostructures 24B are for the upper nanostructure-FET 10U. In other embodiments, the stacking transistors may be applied to other types of transistors, Nano Field-effect Transistors (nano-FETs), Fin Field Effect Transistors (finFETs), or the like.

Gate dielectrics 78 encircle the respective semiconductor nanostructures 24. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate selected ones of the source/drain regions 62 and/or selected ones of the gate electrodes 80. FIG. 1 further illustrates reference cross-section A-A′. Reference cross-section A-A′ may be a vertical cross-section that is parallel to a longitudinal axis of the semiconductor nanostructures 24 of the stacking transistor 10 and in a direction of, for example, a current flow between the source/drain regions 62 of the stacking transistor 10.

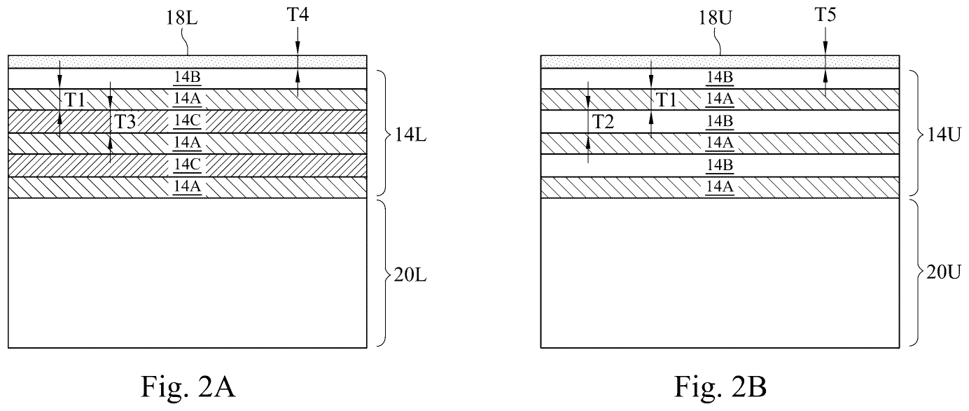

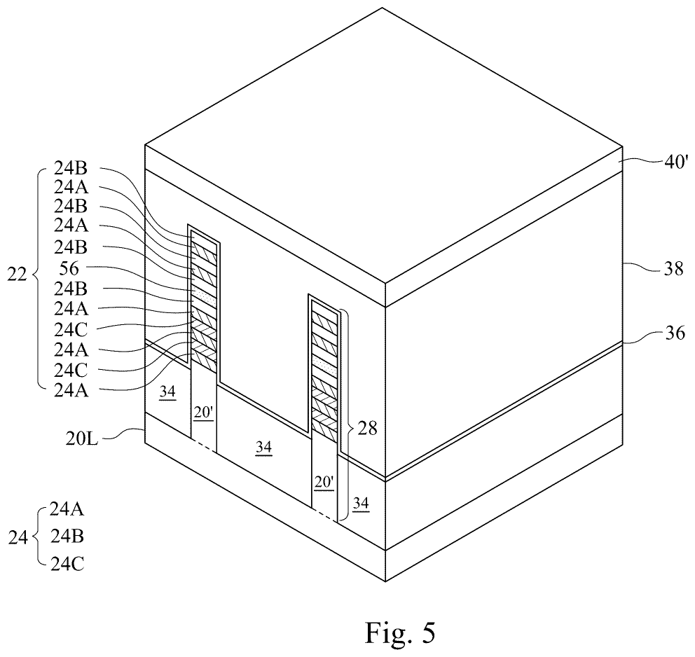

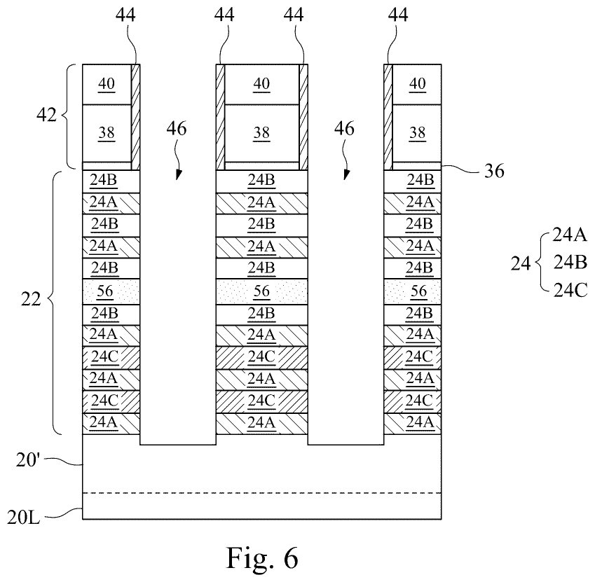

FIGS. 2A through 10 are various views of intermediate stages in the manufacturing of a stacking transistor including lower nanostructure-FETs and upper nanostructure-FETs, which may be similar to the stacking transistor 10 shown in FIG. 1, in accordance with some embodiments. FIGS. 2A, 2B, 3, and 4 illustrate general cross-sectional views. FIG. 5 is a perspective view similar to FIG. 1. FIGS. 6 through 10 are cross-sectional views of a portion of the structure shown in FIG. 2 along a cross-section similar to the reference cross-section A-A′ shown in FIG. 1.

In FIGS. 2A and 2B, two substrates 20L and 20U are separately provided. FIG. 2A illustrates a substrate 20L, and FIG. 2B illustrates a substrate 20U. In a subsequent process, the substrate 20U may be bonded over the substrate 20L. The substrates 20L and 20U may be semiconductor substrates, such as semiconductor wafer or the like. The substrates 20L and 20U may be may be doped or undoped. The substrates 20L and 20U may comprise materials with a same composition and different crystal orientations. In some embodiments, the substrate 20L comprises silicon with a (110) orientation, and the substrate 20U comprises silicon with a (100) orientation.

A multi-layer stack 14L and a multi-layer stack 14U are formed over the substrate 20L and the substrate 20U, respectively. The multi-layer stack 14L may include alternating dummy semiconductor layers 14A and semiconductor layers 14C, and a semiconductor layer 14B over the alternating dummy semiconductor layers 14A and semiconductor layers 14C. The multi-layer stack 14U may include alternating dummy semiconductor layers 14A and semiconductor layers 14B. Numbers of the dummy semiconductor layers 14A, the semiconductor layers 14B, and the semiconductor layers 14C in the multi-layer stack 14L and the multi-layer stack 14U shown in FIGS. 2A and 2B are provided as an example, and other numbers of the dummy semiconductor layers 14A, the semiconductor layers 14B, and the semiconductor layers 14C in the multi-layer stack 14L and the multi-layer stack 14U are contemplated.

The dummy semiconductor layers 14A, the semiconductor layer 14B, and the semiconductor layers 14C over the substrate 20L may comprise different materials with the same crystal orientation as the substrate 20L, such as the (110) orientation. The dummy semiconductor layers 14A and the semiconductor layers 14B over the substrate 20U may comprise different materials with the same crystal orientation as the substrate 20U, such as the (100) orientation. The semiconductor layer 14B over the substrate 20L and the semiconductor layers 14B over the substrate 20U may comprise materials with a same composition and different crystal orientations. The semiconductor layers 14C over the substrate 20L and the semiconductor layers 14B over the substrate 20U may comprise different materials with different crystal orientations. The material of the dummy semiconductor layers 14A may have etching selectivity to the materials of the semiconductor layer 14B and the semiconductor layers 14C.

In subsequent processes, as described in greater detail below, the semiconductor layers 14C over the substrate 20L may be patterned to form channel regions of the lower nanostructure-FETs, and the semiconductor layers 14B over the substrate 20U may be patterned to form channel regions of the upper nanostructure-FETs. The patterned dummy semiconductor layers 14A may be removed without substantially removing the patterned semiconductor layers 14B and 14C. Since the semiconductor layers 14C over the substrate 20L and the semiconductor layers 14B over the substrate 20U may comprise materials with different compositions and crystal orientations, carrier mobilities in the channel regions of the lower nanostructure-FETs and the channel regions of the upper nanostructure-FETs may be both improved, thereby improving a performance of the subsequently formed stacking transistor.

In some embodiments, the dummy semiconductor layers 14A comprise silicon germanium with a first germanium concentration (e.g., atomic percentage). In some embodiments, the semiconductor layers 14B over the substrate 20U comprises a semiconductor material suitable for n-type channel regions, such as silicon or the like, with the (100) orientation. In some embodiments, the semiconductor layer 14B over the substrate 20L comprises silicon or the like with the (110) orientation. In some embodiments, the semiconductor layers 14C comprises a semiconductor material suitable for p-type channel regions, such as silicon germanium, or the like, with the (110) orientation and a second germanium concentration (e.g., atomic percentage) different from the first germanium concentration.

In some embodiments, the first germanium concentration is in a range from about 35% to about 60%, the second germanium concentration is in a range from about 15% to about 30%, and the first germanium concentration is larger than the second germanium concentration. In some embodiments, the first germanium concentration is in a range from about 15% to about 30%, the second germanium concentration is in a range from about 35% to about 60%, and the first germanium concentration is smaller than the second germanium concentration.

The dummy semiconductor layers 14A may have a first thickness T1 in range from about 3 nm to about 12 nm. The semiconductor layers 14B may have a second thickness T2 in range from about 3 nm to about 12 nm. In some embodiments, the second thickness T2 is larger than the first thickness T1. The semiconductor layers 14C may have a third thickness T3 in range from about 3 nm to about 12 nm. In some embodiments, the third thickness T3 is larger than the first thickness T1. In some embodiments, the third thickness T3 equals the second thickness T2.

The dummy semiconductor layers 14A, the semiconductor layers 14B, and the semiconductor layers 14C may be formed by a series of suitable growth processes, such as vapor phase epitaxy (VPE), molecular beam epitaxy (MBE), or the like; a series of suitable deposition processes, such as chemical vapor deposition (CVD), atomic layer deposition (ALD), or the like; or combinations thereof. In some embodiments, the dummy semiconductor layers 14A, the semiconductor layers 14B, and the semiconductor layers 14C are formed by a series of CVD processes, at a temperature in a range from about 500° C. to about 760° C. and under a pressure in a range from about 1 torr to about 100 torr. In such embodiments, silane, disilane, dicholorosilane, diiodosilane, germane, germanium tetrachloride, germanium diiodide, hydrochloric acid, hydrogen chlorine, bromine, iodine may be used as precursors, and the different germanium concentrations of the dummy semiconductor layers 14A and the semiconductor layers 14C may be achieved by controlling flow rates of selected precursors during the corresponding deposition processes.

Bonding layers 18L and 18U may be formed on the multi-layer stack 14L and the multi-layer stack 14U, respectively. The bonding layers 18L and 18U may facilitate a subsequent bonding process between the structures shown in FIGS. 2A and 2B. The bonding layers 18L and 18U may comprise dielectric materials suitable for a dielectric-to-dielectric bonding process, such as silicon oxide, silicon nitride, silicon oxynitride, silicon carbonitride, silicon oxycarbonitride, or the like. In some embodiments, the bonding layers 18L and 18U comprise a same dielectric material. The bonding layer 18L may have a thickness T4 in range from about 3 nm to about 15 nm. The bonding layer 18U may have a thickness T5 in range from about 3 nm to about 15 nm. In some embodiments, the thickness T4 and the thickness T5 are equal. The bonding layers 18L and 18U may be formed by suitable deposition processes, such as physical vapor deposition (PVD), CVD, ALD, or the like.

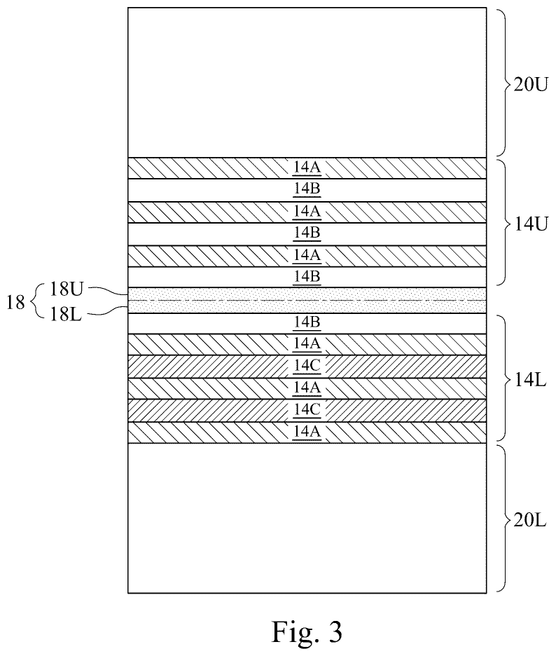

In FIG. 3, the structure shown in FIG. 2A is flipped over and bonded to the structure shown in FIG. 2B by bonding the bonding layers 18L and 18U together. The bonding layers 18L and 18U may be bonded together using a suitable bonding process, such as dielectric-to-dielectric bonding process, or the like. After the bonding process, the lower bonding layer 18L and the bonding layer 18U may be collectively referred to as a bonded layer 18. An interface between the bonding layer 18L and the bonding layer 18U may disappear or remain after the bonding process. The interface between the bonding layer 18L and the bonding layer 18U is omitted in FIG. 3 and subsequent figures for illustrative purposes. The bonding process may include a surface treatment step, such as plasma treatment or the like, followed by a cleaning step performed on surfaces of the bonding layers 18L and 18U. Afterwards, the bonding layer 18U may be placed over and aligned to the bonding layer 18L. The bonding layer 18L and the bonding layer 18U may be then pressed against each other to initiate the bonding between the bonding layer 18L and the bonding layer 18U at room temperature during a pressing step. The bonding layer 18L and the bonding layer 18U may be then heated during an annealing step to strength the bonding between the bonding layer 18L and the bonding layer 18U.

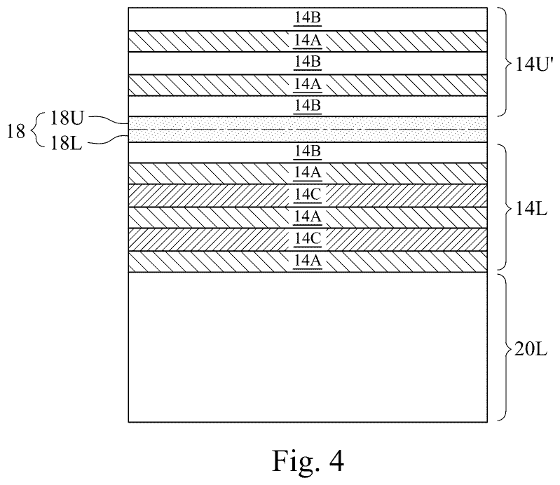

In FIG. 4, a thinning process is performed to remove the substrate 20U and a dummy semiconductor layer 14A of the multi-layer stack 14U in contact with the substrate 20U. After the thinning process, a remaining portion of the multi-layer stack 14U may be referred to as the multi-layer stack 14U′. After the thinning process, a surface of the semiconductor layer 14B of the multi-layer stack 14U may be exposed. The thinning process may be a grinding process, a chemical mechanical polish (CMP), an etching process, combinations thereof, or the like. The etching process may be a dry etching process, a wet etching process, combinations thereof, or the like.

In FIG. 5, the multi-layer stack 14U, the bonded layer 18, the multi-layer stack 14L, and the substrate 20L are patterned to form semiconductor strips 28 extending upwards from the substrate 20L. Each of semiconductor strips 28 may include a semiconductor fin 20′, which may be a patterned portion of the substrate 20L, and a multi-layer stack 22 over the semiconductor fin 20′. Each multi-layer stack 22 may include dummy nanostructures 24A, semiconductor nanostructures 24B, semiconductor nanostructures 24C, and a dielectric isolation structure 56. The dummy nanostructures 24A may be formed by patterning the dummy semiconductor layers 14A in the structure shown in FIG. 4. The semiconductor nanostructures 24B may be formed by patterning the semiconductor layers 14B in the structure shown in FIG. 4. The semiconductor nanostructures 24C may be formed by patterning the semiconductor layers 14C in the structure shown in FIG. 4. The dielectric isolation structure 56 may be formed by patterning the bonded layer 18 in the structure shown in FIG. 4. The dummy nanostructures 24A, the semiconductor nanostructures 24B, and the semiconductor nanostructures 24C may be collectively referred to as semiconductor nanostructures 24.

As described in greater detail below, the semiconductor nanostructures 24C below the dielectric isolation structures 56 may be used as the channel regions of the lower nanostructure-FETs, and the semiconductor nanostructures 24B above the dielectric isolation structures 56 may be used as the channel regions of the upper nanostructure-FETs. The dielectric isolation structures 56 along with the semiconductor nanostructures 24B in contact with the dielectric isolation structures 56, which may be dummy features, may define boundaries between the lower nanostructure-FETs and the upper nanostructure-FETs. The semiconductor fins 20′, the semiconductor nanostructures 24, and the dielectric isolation structures 56 may be formed by suitable patterning processes, which may include suitable masking and suitable photolithography processes.

As also illustrated in FIG. 5, STI regions 34 are formed over the substrate 20L and between adjacent semiconductor fins 20′. The STI regions 34 may include a dielectric liner and a dielectric material over the dielectric liner. The dielectric liner and the dielectric material may include dielectric materials such as, silicon oxide, silicon nitride, the like, or a combination thereof. The STI regions 34 may be formed by depositing the dielectric layer(s) by ALD, CVD, or the like, and then performing a planarization process, such as CMP or the like to remove excess portions of the dielectric materials. An annealing process may be performed after the planarization process. Then, the dielectric layers(s) may be further recessed by suitable etching processes to form the STI regions 34. The semiconductor fins 20′ may protrude higher than the STI regions 34 after the etching processes.

After the STI regions 34 are formed, dummy gate stacks 42 may be formed over and along sidewalls of the upper portions of the semiconductor strips 28, which may be the portions that protrude higher than the STI regions 34. Forming the dummy gate stacks 42 may include forming dummy dielectric layer 36 on the semiconductor strips 28. Dummy dielectric layer 36 may be formed of a dielectric material such as, silicon oxide, silicon nitride, combinations thereof, or the like, and may be deposited or thermally grown. A dummy gate layer 38 may be formed over the dummy dielectric layer 36. The dummy gate layer 38 may be formed of amorphous silicon, polycrystalline silicon, polycrystalline silicon-germanium, or the like. The dummy gate layer 38 may be deposited by PVD, CVD, or the like. The dummy gate layer 38 may be then planarized by CMP or the like.

A mask layer 40′ is then formed over the planarized dummy gate layer 38. The mask layer 40′ may comprise, silicon nitride, silicon oxynitride, or the like. Then the mask layer 40′ may be patterned by suitable photolithography and etching processes to form a mask 40 (shown in FIG. 6), which may be then used to pattern dummy gate layer 38 and the dummy dielectric layer 36. The mask 40, the remaining portions of the dummy gate layer 38, and the dummy dielectric layer 36 may be referred to as the dummy gate stacks 42 (shown in FIG. 6).

In FIG. 6, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a suitable deposition process such as CVD, ALD, or the like. The mask 40, and the gate spacers 44 may be used to protect the dummy gate layers 38 during subsequent etching processes.

Subsequently, source/drain recesses 46 are formed in semiconductor strips 28. The source/drain recesses 46 are formed through etching, and may extend through the multi-layer stacks 22 and into the semiconductor fins 20′. The bottom surfaces of the source/drain recesses 46 may be above, below, or level with the top surfaces of the STI regions 34 (not shown). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a selected depth.

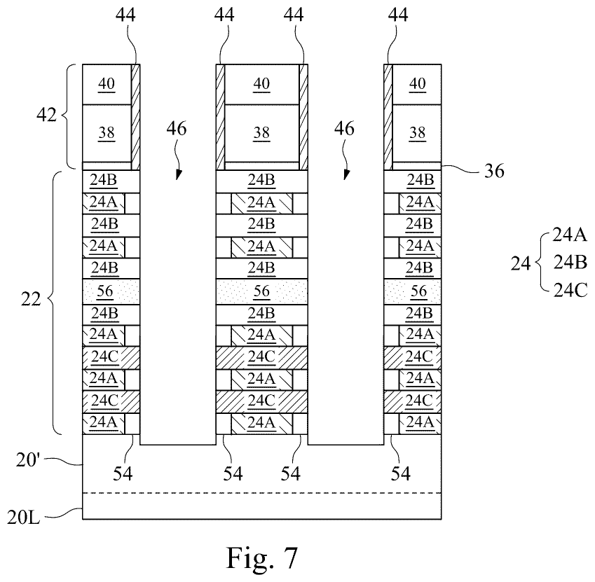

In FIG. 7, the dummy nanostructures 24A are partially removed and inner spacers 54 are formed. After the dummy nanostructures 24A are partially removed, sidewalls of the dummy nanostructures 24A may be recessed. The dummy nanostructures 24A may be partially removed by a suitable etching process. The etching process may selectively remove the materials of the dummy nanostructures 24A without significantly removing the materials of the semiconductor nanostructures 24B, the semiconductor nanostructures 24C, the dielectric isolation structures 56, or the semiconductor fins 20′. The etching process may be a dry etching process using etchant(s), such as chlorine, and/or the like. The inner spacers 54 may be formed on the recessed sidewalls of the dummy nanostructures 24A. Source/drain regions may be subsequently formed in the source/drain recesses 46, and the remaining portions of dummy nanostructures 24A may be replaced with corresponding gate structures in subsequent processes. The inner spacers 54 may be used to isolate the subsequently formed source/drain regions from the subsequently formed gate structures.

The inner spacers 54 may be formed by conformally depositing a suitable dielectric material on the sidewalls the dummy nanostructures 24A. The dielectric material may be then etched to remove excess portions. The dielectric material may be a hard dielectric material, such as a carbon-containing dielectric material, such as silicon oxycarbonitride, silicon oxycarbide, silicon carbonitride, or the like. Other low-dielectric constant (low-k) materials having a k-value less than about 3.5 may be utilized. The dielectric material may be formed by a suitable deposition process, such as ALD, CVD, or the like. The etching of the dielectric material may be an anisotropic etching process or an isotropic etching process.

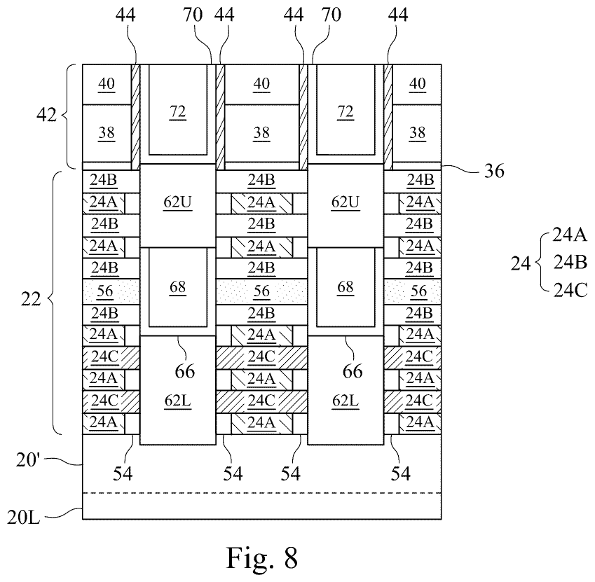

In FIG. 8, lower epitaxial source/drain regions 62L, upper epitaxial source/drain regions 62U, first contact etch stop layers (CESLs) 66, first inter-layer dielectrics (ILDs) 68, second CESLs 70, and second ILDs 72 are formed in the source/drain recesses 46. The lower epitaxial source/drain region 62L may refer to a source or a drain, individually or collectively dependent upon the context. The upper epitaxial source/drain region 62U may refer to a source or a drain, individually or collectively dependent upon the context. The lower epitaxial source/drain regions 62L are formed in the lower portions of the source/drain recesses 46. The lower epitaxial source/drain regions 62L may be in contact with the semiconductor nanostructures 24C and may not be in contact with the semiconductor nanostructures 24B. The upper epitaxial source/drain regions 62U may be in contact with the semiconductor nanostructures 24B and may not be in contact with the semiconductor nanostructures 24C. The lower epitaxial source/drain regions 62L may be in contact with the inner spacers 54, which electrically insulate the lower epitaxial source/drain regions 62L from the dummy nanostructures 24A. The upper epitaxial source/drain regions 62U may be in contact with inner spacers 54, which electrically insulate the upper epitaxial source/drain regions 62U from the dummy nanostructures 24A. The dummy nanostructures 24A may be replaced with replacement gates in subsequent processes.

The lower epitaxial source/drain regions 62L are epitaxially grown from exposed surfaces of the semiconductor nanostructures 24C, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the semiconductor nanostructures 24B (e.g., sidewalls) may be masked to prevent undesired epitaxial growth on the semiconductor nanostructures 24B. After the lower epitaxial source/drain regions 62L are grown, the masks on the semiconductor nanostructures 24B may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy processes. In other embodiments, adjacent lower epitaxial source/drain regions 62L merge with each other.

The first CESLs 66 and the first ILDs 68 are formed over the lower epitaxial source/drain regions 62L. The first CESLs 66 may be formed of a dielectric material having a high etching selectivity from the etching of the first ILDs 68, such as silicon nitride, silicon oxide, silicon oxynitride, or the like, which may be formed by any suitable deposition process, such as CVD, ALD, or the like. The first ILDs 68 may be formed of a dielectric material, which may be deposited by any suitable method, such as CVD, plasma-enhanced CVD (PECVD), or FCVD. The applicable dielectric material of the first ILDs 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILDs 68, followed by a planarization process and then an etch-back process. In some embodiments, the first ILDs 68 are etched first, leaving the conformal CESL layer unetched. An anisotropic etching process is then performed to remove the portions of the conformal CESL layer higher than the recessed first ILDs 68. After the recessing, the sidewalls of the semiconductor nanostructures 24B are exposed.

Upper epitaxial source/drain regions 62U are then formed in the upper portions of the source/drain recesses 46. The upper epitaxial source/drain regions 62U may be epitaxially grown from exposed surfaces of the semiconductor nanostructures 24B. The materials of upper epitaxial source/drain regions 62U may be selected from the same candidate group of materials for forming lower epitaxial source/drain regions 62L, depending on the selected conductivity type of upper epitaxial source/drain regions 62U. The conductivity type of the upper epitaxial source/drain regions 62U may be opposite the conductivity type of the lower epitaxial source/drain regions 62L in embodiments where the stacking transistor is a CFET. The upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant.

As a result of the epitaxy processes used for forming the upper epitaxial source/drain regions 62U, upper surfaces of the upper epitaxial source/drain regions 62U have facets which expand laterally outward beyond sidewalls of the multi-layer stacks 22. In some embodiments, adjacent upper epitaxial source/drain regions 62U remain separated after the epitaxy process is completed. In other embodiments, adjacent upper epitaxial source/drain regions 62U merge with each other.

After the upper epitaxial source/drain regions 62U are formed, second CESLs 70 and second ILDs 72 are formed. The materials and the formation methods may be similar to the materials and the formation methods of the first CESLs 66 and the first ILDs 68, respectively. The formation process may include depositing the conformal CESL layer and the second ILDs 72, and performing a planarization process to remove the excess portion of the corresponding layers. After the planarization process, top surfaces of the second ILDs 72, the gate spacers 44, and mask 40 are substantially coplanar (within process variations). In the illustrated embodiment, the mask 40 remain after the removal process. In other embodiments, the mask 40 are removed such that the top surfaces of the dummy gate layers 38 are exposed.

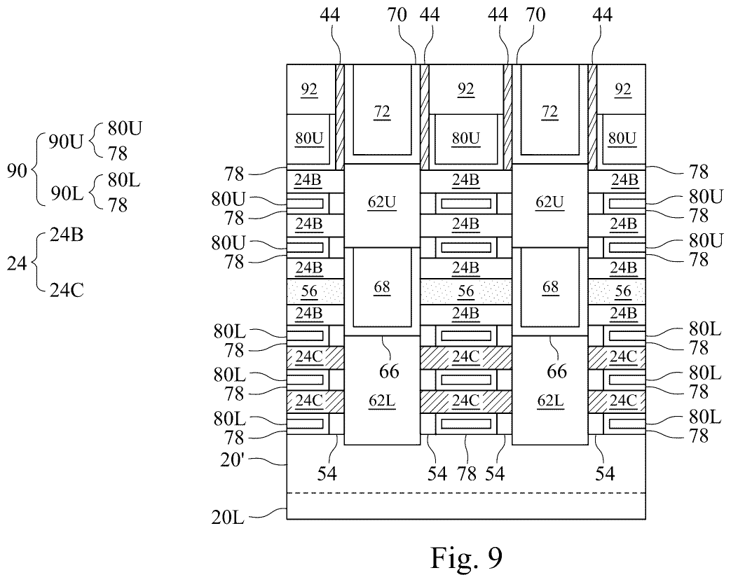

In FIG. 9, a gate replacement process to replace the dummy gate stacks 42 and the dummy nanostructures 24A with gate structures 90 is performed. The gate replacement process may include first removing the dummy gate stacks 42 and the dummy nanostructures 24A. The dummy gate stacks 42 may be removed by one or more suitable etching processes. The dummy nanostructures 24A may be then removed by an additional suitable etching process. The etching process that removes the dummy nanostructures 24A may selectively remove the material of the dummy nanostructures 24A without significantly removing the materials of the semiconductor nanostructures 24B and the semiconductor nanostructures 24C. The etching process that removes the dummy nanostructures 24A may be a wet isotropic etching process and etchants such as hydrofluoric acid, nitric acid, hydrogen peroxide, or the like may be used.

Then, gate dielectrics 78 may be formed on the exposed surfaces of the semiconductor nanostructures 24 and the inner spacers 54. In some embodiments, the gate dielectrics 78 wrap around all (e.g., four) sides of selected semiconductor nanostructures 24. Specifically, the gate dielectrics 78 may be formed on the top surfaces of the semiconductor fins 20′; on the top surfaces, the sidewalls, and the bottom surfaces of the selected semiconductor nanostructures 24; and on the sidewalls of the inner spacers 54. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include MBD, ALD, PECVD, and the like followed by a planarization process, such as CMP to remove portions of the gate dielectrics 78 above the second ILD 72. Although single-layered gate dielectrics 78 may be illustrated, the gate dielectrics 78 may include multiple layers, such as an interfacial layer and an overlying high-k dielectric layer.

Lower gate electrodes 80L may be formed on the gate dielectrics 78 around the semiconductor nanostructures 24C. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material. The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the semiconductor nanostructures 24B.

The lower gate electrodes 80L may be formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

In some embodiments, isolation layers (not illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the semiconductor nanostructures 24B.

Upper gate electrodes 80U may be formed on the isolation layers described above (if present) or the lower gate electrodes 80L. The upper gate electrodes 80U may be formed around the semiconductor nanostructures 24B. The upper gate electrodes 80U may be formed of the same or similar materials and formed by same or similar processes as the lower gate electrodes 80L. The upper gate electrodes 80U may be formed of material(s) that are suitable for the device type of the upper nanostructure-FETs. For example, the upper gate electrodes 80U may include one or more work function tuning layer(s) (e.g., n-type work function tuning layer(s) or p-type work function tuning layer(s)) formed of material(s) that are suitable for the device type of the upper nanostructure-FETs. Although single-layered upper gate electrodes 80U are illustrated, the upper gate electrodes 80U may include any number of work function tuning layers, any number of barrier layers, any number of glue layers, and a fill material.

Gate masks 92 may be formed on the upper gate structures 90U. The formation process may include recessing the upper gate structures 90U, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 72 and to level top surfaces of the gate masks 92 and the second ILD 72. The planarization process may be CMP, etch-back, combinations thereof, or the like. After the planarization process, the top surfaces of the gate masks 92, the gate dielectrics 78, the second ILD 72, and the gate spacers 44 may be substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L).

The semiconductor nanostructures 24C below the dielectric isolation structures 56 and between the lower epitaxial source/drain regions 62L may be wrapped around by the lower gate structures 90L and used to as the channel regions of the lower nanostructure-FETs, which may p-type devices. The semiconductor nanostructures 24B above the dielectric isolation structures 56 and between the upper epitaxial source/drain regions 62U may be wrapped around by the upper gate structures 90U and may be used to form the channel regions of the upper nanostructure-FETs, which may n-type devices. The semiconductor layers 14C over the substrate 20L may comprise silicon germanium with the (110) orientation, which may lead to improved carrier mobilities in the channel regions of the p-type devices, and the semiconductor layers 14B over the substrate 20U may comprise silicon with the (100) orientation, which may lead to improved carrier mobilities in the channel regions of the n-type devices. As a result, the carrier mobilities in the channel regions of the lower nanostructure-FETs and the channel regions of the upper nanostructure-FETs may be both improved, thereby improving the performance of the subsequently formed stacking transistor.

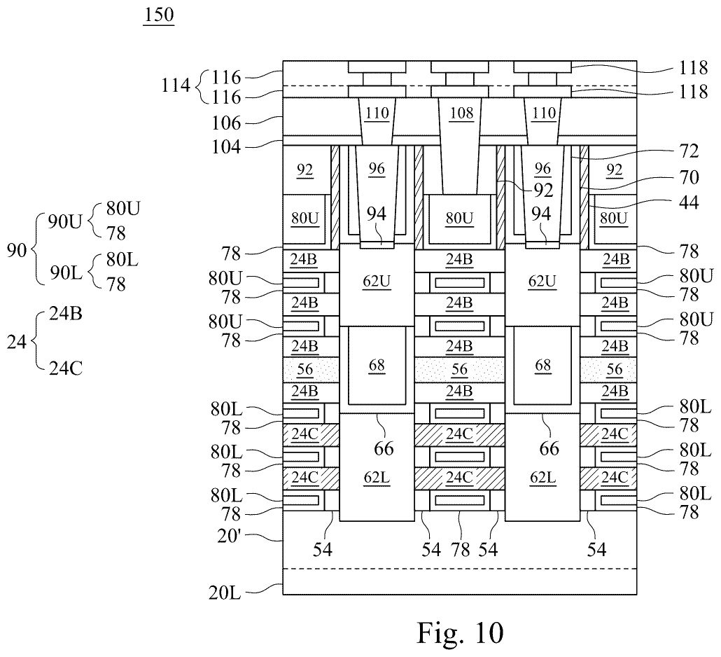

In FIG. 10, metal-semiconductor alloy regions 94 are formed on the upper epitaxial source/drain regions 62U and source/drain contacts 96 are formed through the second ILD 72 to electrically couple to the upper epitaxial source/drain regions 62U and/or the lower epitaxial source/drain regions 62L. Initially, openings may be formed through the second ILD 72 and the second CESL 70 using acceptable photolithography and etching processes. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be then performed to remove excess material from the top surfaces of the gate spacers 44 and the second ILD 72. The remaining liner and conductive material form the source/drain contacts 96 in the openings. In some embodiments, a planarization process such as CMP, etch-back, combinations thereof, or the like is utilized. After the planarization process, the top surfaces of the gate spacers 44, the second ILD 72, and the source/drain contacts 96 are substantially coplanar (within process variations).

Optionally, metal-semiconductor alloy regions 94 are formed at the interfaces between the source/drain regions 62 and the source/drain contacts 96. The metal-semiconductor alloy regions 94 may be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 may be formed before the material(s) of the source/drain contacts 96 by depositing a metal in the openings for the source/drain contacts 96 and then performing an annealing process. The metal may be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the annealing process, a cleaning process, such as a wet clean, may be performed to remove any residual metal from the openings for the source/drain contacts 96, such as from surfaces of the metal-semiconductor alloy regions 94. The material(s) of the source/drain contacts 96 can then be formed on the metal-semiconductor alloy regions 94.

A third CESL 104 and a third ILD 106 are then formed. In some embodiments, the third CESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the third CESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the third ILD 106. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate structures 90L and the lower epitaxial source/drain regions 62L may be made through a backside of the substrate 20 (e.g., a side opposite to the front-side interconnect structure 114). The structure in FIG. 10 may be referred to as the stacking transistor 150.

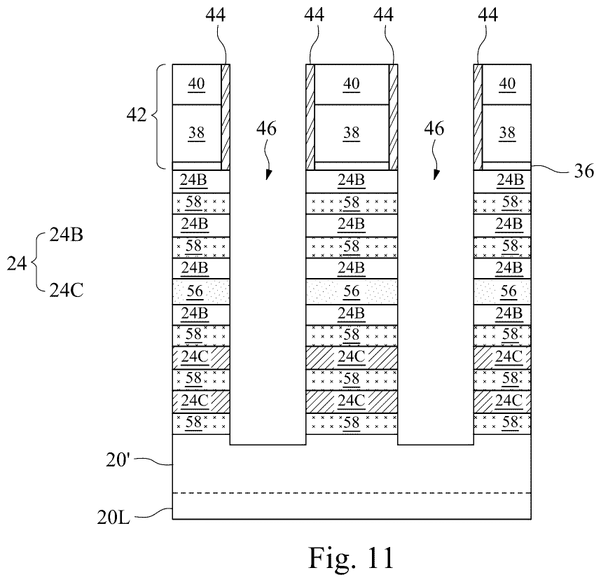

FIGS. 11 through 13 are various views of intermediate stages in the manufacturing of the stacking transistor 150, in accordance with some embodiments. The structure shown in FIG. 11 is based on the structure shown in FIG. 6, wherein like numerals refer to like features formed by like processes. In FIG. 11, sacrificial structures 58 are formed to replace the dummy nanostructures 24A. The dummy nanostructures 24A may be removed by an etching process similar to the etching process used to remove the dummy nanostructures 24A described with respect to FIG. 9. Replacing the dummy nanostructures 24A with the sacrificial structures 58 may provide advantages. For example, in subsequent processes, one or more high temperature processes may be performed, such as a source/drain annealing process, which may cause the material of the dummy nanostructures 24A, if not removed, to intermix with the materials of the semiconductor nanostructures 24B and the semiconductor nanostructures 24C. The one or more high temperature processes may also increase roughness at interfaces between the semiconductor nanostructures 24B and the dummy nanostructures 24A as well as interfaces between the semiconductor nanostructures 24C and the dummy nanostructures 24A. By replacing the dummy nanostructures 24A with the sacrificial structures 58 prior to the one or more high temperature processes, manufacturing defects may be reduced.

Forming the sacrificial structures 58 may include depositing a sacrificial material layer in the source/drain recesses 46 and spaces where the dummy nanostructures 24A used to occupy. The sacrificial material layer may be deposited by a conformal deposition process, such as CVD, ALD, or the like. The sacrificial material layer may comprise an insulating material, such as silicon oxide, or the like, which may have a high etching selectivity to the dielectric isolation structure 56, the semiconductor nanostructures 24B, and the semiconductor nanostructures 24C. The sacrificial material layer may then be partially removed to form the sacrificial structures 58. The etching process may be isotropic or anisotropic. In some embodiments, the sacrificial material layer is etched by a wet etching process using diluted HF, or the like. Although sidewalls of the sacrificial structures 58 are illustrated as being aligned with sidewalls of the semiconductor nanostructures 24, the sidewalls of the sacrificial structures 58 may be recessed from the sidewalls of the semiconductor nanostructures 24 in some embodiments.

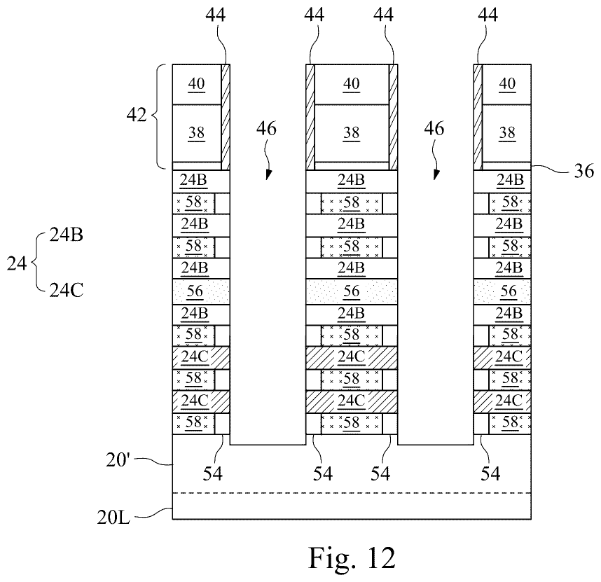

FIG. 12 shows a structure which may be obtained after similar processes described with respect to FIG. 7 are performed on the structure shown in FIG. 11, wherein like numerals refer to like features formed by like processes. As shown in FIG. 12, the sacrificial structures 58 are partially removed by recessing sidewalls of the sacrificial structures 58 and the inner spacers 54 are formed on the recessed sidewalls of the sacrificial structures 58. In some embodiments, recessing sidewalls of the sacrificial structures 58 is done during the etching process used to partially remove sacrificial material layer described with respect to FIG. 11. In some embodiments, recessing sidewalls of the sacrificial structures 58 is done by another etching process similar to the etching process used to partially remove sacrificial material layer described with respect to FIG. 11.

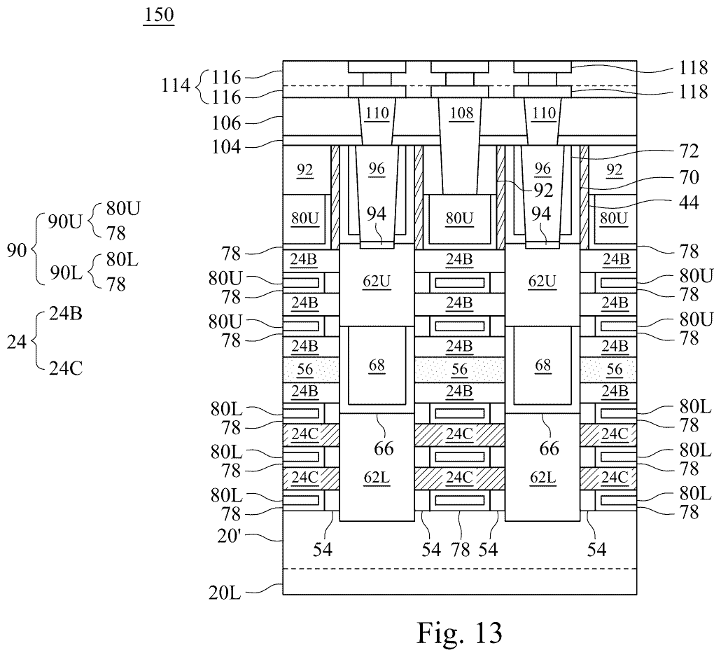

FIG. 13 shows the stacking transistor 150 which may be obtained after similar processes described with respect to FIGS. 8, 9, and 10 are performed on the structure shown in FIG. 12, wherein like numerals refer to like features formed by like processes. As shown in FIG. 13, the sacrificial structures 58 are removed and the gate structures 90 are formed in spaces where the sacrificial structures 58 used to occupy. The sacrificial structures 58 may be removed at a similar step where the dummy nanostructures 24A are removed as described with respect to FIG. 9. The sacrificial structures 58 may be removed by an etching process similar to the etching process used to partially remove sacrificial material layer described with respect to FIG. 11.

The embodiments of the present disclosure have some advantageous features. Since the semiconductor layers 14C and the semiconductor layers 14B may be formed to comprise materials with different compositions and crystal orientations, the carrier mobilities in the channel regions of the upper nanostructure-FETs and the lower nanostructure-FETs may be both improved. As a result, the performance of the stacking transistor 150 may be improved.

In an embodiment, a semiconductor device includes a first nanostructure, wherein the first nanostructure includes a first material with a first composition and a first crystal orientation; a first source/drain region on a sidewall of the first nanostructure; a first gate structure around the first nanostructure; a second nanostructure over the first nanostructure, wherein the second nanostructure includes a second material with a second composition and a second crystal orientation, wherein the first composition is different from the second composition, and wherein the first crystal orientation is different from the second crystal orientation; a second source/drain region on a sidewall of the second nanostructure; and a second gate structure around the second nanostructure. In an embodiment, the first crystal orientation is (110) and the second crystal orientation is (100). In an embodiment, the first composition is silicon germanium and the second composition is silicon. In an embodiment, the first composition has a germanium concentration in a range from 35% to 60%. In an embodiment, the first composition has a germanium concentration in a range from 15% to 30%. In an embodiment, the first crystal orientation is (110) and the second crystal orientation is (100). In an embodiment, the semiconductor further includes a dielectric isolation structure between the first nanostructure and the second nanostructure.

In an embodiment, a method of forming a semiconductor device includes forming a first multilayer stack, wherein the first multilayer stack includes: a first nanostructure, wherein the first nanostructure has a first material with a first composition and a first crystal orientation; a first dummy nanostructure over the first nanostructure; a second nanostructure over the first dummy nanostructure, wherein the second nanostructure has a second material with a second composition and a second crystal orientation, wherein the first composition is different from the second composition, and wherein the first crystal orientation is different from the second crystal orientation; a second dummy nanostructure over the second nanostructure; growing a first source/drain region on a sidewall of the first nanostructure; growing a second source/drain region on a sidewall of the second nanostructure; and replacing the first dummy nanostructure with a first gate structure and the second dummy nanostructure with a second gate structure. In an embodiment, the first composition is silicon germanium and the second composition is silicon. In an embodiment, the first crystal orientation is (110) and the second crystal orientation is (100). In an embodiment, the method further includes forming a dielectric layer between the first source/drain region and the second source/drain region. In an embodiment, forming the first multilayer stack includes: growing the first nanostructure over a first substrate, wherein the first substrate has the first crystal orientation; growing the first dummy nanostructure over the first nanostructure; and depositing a first bonding layer over the first dummy nanostructure. In an embodiment, forming the first multilayer stack further includes: growing the second nanostructure over a second substrate, wherein the second substrate has the second crystal orientation; growing the second dummy nanostructure over the second nanostructure; and depositing a second bonding layer over the second dummy nanostructure. In an embodiment, forming the first multilayer stack further includes: bonding the first bonding layer with the second bonding layer by dielectric-to-dielectric bonding; and removing the second substrate.

In an embodiment, a method of forming a semiconductor device includes forming a first structure, wherein the first structure includes: a first semiconductor layer over a first substrate, wherein the first semiconductor layer includes a first material; a first bonding layer over the first semiconductor layer; forming a second structure, wherein the second structure includes: a second semiconductor layer over a second substrate, wherein the second semiconductor layer includes a second material, wherein the first material and the second material have different compositions; a second bonding layer over the second semiconductor layer; bonding the first bonding layer and the second bonding layer to form a multilayer stack; forming a recess in the multilayer stack, wherein the recess extends through the first semiconductor layer the first bonding layer, the second semiconductor layer and the second bonding layer; and forming a first source/drain region and a second source/drain region over the first source/drain region in the recess. In an embodiment, the first material and the second material have different crystal orientations. In an embodiment, the first structure further includes a first dummy layer between the first bonding layer and the first semiconductor layer, wherein the method further including: removing the first dummy layer to form a first opening; and forming a dielectric sacrificial structure in the first opening before forming the first source/drain region. In an embodiment, the method further includes removing the dielectric sacrificial structure after forming the first source/drain region. In an embodiment, the first structure further includes a first dummy layer between the first bonding layer and the first semiconductor layer, wherein the first material is silicon germanium with a first germanium concentration, wherein the first dummy layer includes silicon germanium with a second germanium concentration, and wherein the first germanium concentration is larger than the second germanium concentration. In an embodiment, the first structure further includes a first dummy layer between the first bonding layer and the first semiconductor layer, wherein the first material is silicon germanium with a first germanium concentration, wherein the first dummy layer includes silicon germanium with a second germanium concentration, and wherein the first germanium concentration is smaller than the second germanium concentration.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first nanostructure, wherein the first nanostructure comprises a first material with a first composition and a first crystal orientation;
a first source/drain region on a sidewall of the first nanostructure;
a first gate structure around the first nanostructure;
a second nanostructure over the first nanostructure, wherein the second nanostructure comprises a second material with a second composition and a second crystal orientation, wherein the first composition is different from the second composition, and wherein the first crystal orientation is different from the second crystal orientation;
a second source/drain region on a sidewall of the second nanostructure; and
a second gate structure around the second nanostructure.

2. The semiconductor device of claim 1, wherein the first crystal orientation is (110) and the second crystal orientation is (100).

3. The semiconductor device of claim 1, wherein the first composition is silicon germanium and the second composition is silicon.

4. The semiconductor device of claim 3, wherein the first composition has a germanium concentration in a range from 35% to 60%.

5. The semiconductor device of claim 3, wherein the first composition has a germanium concentration in a range from 15% to 30%.

6. The semiconductor device of claim 3, wherein the first crystal orientation is (110) and the second crystal orientation is (100).

7. The semiconductor device of claim 1, further comprising a dielectric isolation structure between the first nanostructure and the second nanostructure.

8. A method of forming a semiconductor device, the method comprising:
forming a first multilayer stack, wherein the first multilayer stack comprises:
a first nanostructure, wherein the first nanostructure has a first material with a first composition and a first crystal orientation;
a first dummy nanostructure over the first nanostructure;
a second nanostructure over the first dummy nanostructure, wherein the second nanostructure has a second material with a second composition and a second crystal orientation, wherein the first composition is different from the second composition, and wherein the first crystal orientation is different from the second crystal orientation;
a second dummy nanostructure over the second nanostructure;
growing a first source/drain region on a sidewall of the first nanostructure;
growing a second source/drain region on a sidewall of the second nanostructure; and
replacing the first dummy nanostructure with a first gate structure and the second dummy nanostructure with a second gate structure.

9. The method of claim 8, wherein the first composition is silicon germanium and the second composition is silicon.

10. The method of claim 9, wherein the first crystal orientation is (110) and the second crystal orientation is (100).

11. The method of claim 8, further comprising forming a dielectric layer between the first source/drain region and the second source/drain region.

12. The method of claim 8, wherein forming the first multilayer stack comprises:
growing the first nanostructure over a first substrate, wherein the first substrate has the first crystal orientation;
growing the first dummy nanostructure over the first nanostructure; and
depositing a first bonding layer over the first dummy nanostructure.

13. The method of claim 12, wherein forming the first multilayer stack further comprises:
growing the second nanostructure over a second substrate, wherein the second substrate has the second crystal orientation;
growing the second dummy nanostructure over the second nanostructure; and
depositing a second bonding layer over the second dummy nanostructure.

14. The method of claim 13, wherein forming the first multilayer stack further comprises:
bonding the first bonding layer with the second bonding layer by dielectric-to-dielectric bonding; and
removing the second substrate.

15. A method of forming a semiconductor device, the method comprising:
forming a first structure, wherein the first structure comprises:
a first semiconductor layer over a first substrate, wherein the first semiconductor layer comprises a first material;
a first bonding layer over the first semiconductor layer;
forming a second structure, wherein the second structure comprises:
a second semiconductor layer over a second substrate, wherein the second semiconductor layer comprises a second material, wherein the first material and the second material have different compositions;
a second bonding layer over the second semiconductor layer;
bonding the first bonding layer and the second bonding layer to form a multilayer stack;
forming a recess in the multilayer stack, wherein the recess extends through the first semiconductor layer the first bonding layer, the second semiconductor layer and the second bonding layer; and
forming a first source/drain region and a second source/drain region over the first source/drain region in the recess.

16. The method of claim 15, wherein the first material and the second material have different crystal orientations.

17. The method of claim 15, wherein the first structure further comprises a first dummy layer between the first bonding layer and the first semiconductor layer, wherein the method further comprising:
removing the first dummy layer to form a first opening; and
forming a dielectric sacrificial structure in the first opening before forming the first source/drain region.

18. The method of claim 17, further comprising removing the dielectric sacrificial structure after forming the first source/drain region.

19. The method of claim 15, wherein the first structure further comprises a first dummy layer between the first bonding layer and the first semiconductor layer, wherein the first material is silicon germanium with a first germanium concentration, wherein the first dummy layer comprises silicon germanium with a second germanium concentration, and wherein the first germanium concentration is larger than the second germanium concentration.

20. The method of claim 15, wherein the first structure further comprises a first dummy layer between the first bonding layer and the first semiconductor layer, wherein the first material is silicon germanium with a first germanium concentration, wherein the first dummy layer comprises silicon germanium with a second germanium concentration, and wherein the first germanium concentration is smaller than the second germanium concentration.
